(19) United States
(12) Patent Application Publication
(10) Pub. No.: US 2024/0183009 A1
(43) Pub. Date: Jun. 6, 2024

(54) HOT-ROLLED COPPER ALLOY SHEET AND SPUTTERING TARGET

(71) Applicant: MITSUBISHI MATERIALS CORPORATION, Tokyo (JP)

(72) Inventors: Yosuke NAKASATO, Kitamoto-shi (JP); Kazunari MAKI, Kitamoto-shi (JP); Yasuhiro TSUGAWA, Sakai-shi (JP); U TANI, Sakai-shi (JP)

(73) Assignee: MITSUBISHI MATERIALS CORPORATION, Tokyo (JP)

(21) Appl. No.: 18/547,597

(22) PCT Filed: Feb. 8, 2022
(86) PCT No.: PCT/JP2022/004909

§ 371 Date: Aug. 23, 2023

(30) Foreign Application Priority Data
Mar. 2, 2021 (JP) 2021-032440

(51) Int. Cl. C22C 9/01; C23C 14/34

(52) U.S. Cl. CPC C22C 9/01; C23C 14/3414; C22F 1/08

(57) ABSTRACT

This hot-rolled copper alloy sheet contains Mg: 0.2 mass % or more and 2.1 mass % or less, and Al: 0.4 mass % or more and 5.7 mass % or less, with a remainder being Cu and inevitable impurities, among the inevitable impurities, an amount of Fe is 0.0020 mass % or less, an amount of O is 0.0020 mass % or less, an amount of S is 0.0030 mass % or less, and an amount of P is 0.0010 mass % or less, a special grain boundary length ratio (Lσ/L) which is a ratio of a sum Lσ of lengths of grain boundaries with 3≤Σ≤29 to a length L of all measured crystal grain boundaries by an EBSD method is 20% or more, and an average crystal grain size μ_{A} in a sheet-thickness central portion is 40 μm or less.

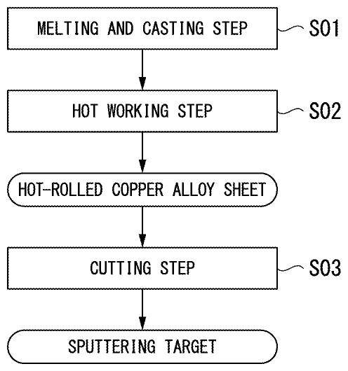

### CROSS-REFERENCE TO RELATED PATENT APPLICATIONS

This application is a U.S. National Phase Application under 35 U.S.C. § 371 of International Patent Application No. PCT/JP2022/004909 filed on Feb. 8, 2022 and claims the benefit of priority to Japanese Patent Application No. 2021-032440 filed on Mar. 2, 2021, the contents of all of which are incorporated herein by reference in their entireties. The International Application was published in Japanese on Sep. 9, 2022 as International Publication No. WO/2022/185858 under PCT Article 21(2).

### FIELD OF THE INVENTION

The present invention relates to a hot-rolled copper alloy sheet and a sputtering target, and the hot-rolled copper alloy sheet is suitably used as a hot worked product such as, for example, a sputtering target, a backing plate, an electron tube for an accelerator, or a magnetron.

### BACKGROUND OF THE INVENTION

In the related art, as a copper alloy sheet used as the above-described hot worked product, a hot-rolled copper alloy sheet produced by a casting step of producing an ingot of a copper alloy and a hot working step of subjecting the ingot to hot working (hot rolling or hot forging) has been generally used.

For example, Japanese Unexamined Patent Application, First Publication No. 2010-103331 discloses a sputtering target for forming a wiring film for a thin film transistor produced using a hot-rolled copper alloy sheet consisting of a Cu—Mg—Ca-based alloy.

The above-described hot-rolled copper alloy sheet is worked into a product having a desired shape by performing cutting such as milling and drilling and plastic working such as bending. In the above-described copper alloy sheet, it is required to refine the crystal grain size and to reduce the residual strain in order to suppress tears and deformation during working.

As for a hot-rolled copper alloy sheet (sputtering target) according to the related art, only the hot working step was provided as a working process, and thus there was a concern that the refinement of crystal grains and the reduction of residual strain may be insufficient even though conditions of the hot working step were controlled. Therefore, it was not possible to sufficiently suppress tears and deformation during working. In addition, in a case where the above-described hot-rolled copper alloy sheet was used as a sputtering target, it was not possible to sufficiently suppress the occurrence of abnormal discharge in high-output sputtering.

### CITATION LIST

### Patent Document

[Patent Document 1]
Japanese Unexamined Patent Application, First Publication No. 2010-103331

### Technical Problem

The present invention is contrived in view of the above-described circumstances, and an object thereof is to provide a hot-rolled copper alloy sheet and a sputtering target, and the hot-rolled copper alloy sheet has excellent cuttability and can sufficiently suppress abnormal discharge even in a case where the hot-rolled copper alloy sheet is used as a sputtering target.

### SUMMARY OF THE INVENTION

### Solution to Problem

In order to solve the problems, the inventors have conducted intensive studies, and as a result, they found that by optimizing the composition and properly controlling the texture in a hot working step, a metal texture with a fine crystal grain size and a high special grain boundary length ratio is obtained, and thus it is possible to provide a hot-rolled copper alloy sheet having excellent cuttability and to suppress the occurrence of abnormal discharge in high-output sputtering in a case where the hot-rolled copper alloy sheet is used as a sputtering target.

The present invention is contrived based on the above-described findings, and a hot-rolled copper alloy sheet according to one aspect of the present invention includes: 0.2 mass % or more and 2.1 mass % or less of Mg; and 0.4 mass % or more and 5.7 mass % or less of Al, with a remainder being Cu and inevitable impurities, in which among the inevitable impurities, an amount of Fe is 0.0020 mass % or less, an amount of O is 0.0020 mass % or less, an amount of S is 0.0030 mass % or less, and an amount of P is 0.0010 mass % or less, when measurement is performed in a measurement area of 150000 μm² or more in a sheet-thickness central portion at a measurement interval of 1 μm by an EBSD method, measurement results are analyzed by data analysis software OIM to obtain a CI value at each measurement point, measurement points where the Cl value is 0.1 or less are removed, an orientation difference between crystal grains is analyzed, and a boundary between adjacent measurement points where an orientation difference between the measurement points is 15° or more is defined as a crystal grain boundary, a special grain boundary length ratio which is a ratio (Lσ/L) of a sum LG of lengths of special grain boundaries with 3≤Σ≤29 to a length L of all measured crystal grain boundaries is 20% or more, and an average crystal grain size μ_{A} in the sheet-thickness central portion is 40 μm or less.

In one aspect of the present invention, the sheet-thickness central portion is a region of 45% to 55% of the total thickness from the surface (interface between the oxide and copper) of the hot-rolled copper alloy sheet in a sheet thickness direction.

According to the hot-rolled copper alloy sheet having the above-described configuration, since the composition is as described above, it is possible to refine the crystal grains and to increase the special grain boundary length ratio by controlling the conditions of the hot working process.

In addition, since the average crystal grain size μ_{A} in the sheet-thickness central portion is 40 μm or less, and the special grain boundary length ratio (Lσ/L) is 20% or more, it is possible to suppress the occurrence of tears during cutting. In addition, when using the hot-rolled copper alloy sheet as a sputtering target, it is possible to suppress the occurrence of abnormal discharge during high-output sputtering.

In one aspect of the present invention, the special grain boundary length ratio (Lσ/L) is obtained by specifying crystal grain boundaries and special grain boundaries by an EBSD measuring device using a field emission scanning electron microscope, and calculating lengths thereof.

The crystal grain boundary is defined as a boundary between two adjacent crystals in which an orientation direction difference between the crystals is 15° or more as a result of two-dimensional cross-sectional observation.

Further, the special grain boundary is defined as a coincidence boundary in which a Σ value satisfies a relationship of 3≤Σ≤29, and the Σ value is crystallographically defined based on the CSL theory (Kronberg et al.: Trans. Met. Soc. AIME, 185, 501 (1949)), and the coincidence boundary is a grain boundary in which the intrinsic corresponding site lattice orientation defect Dq satisfies a relationship of Dq≤15°/15°/Σ^{1/2} (D. G. Brandon: Acta. Metallurgica. Vol. 14, p. 1479, (1966)).

In the hot-rolled copper alloy sheet according to one aspect of the present invention, a standard deviation σ_{A} of crystal grain sizes in the sheet-thickness central portion is preferably 90% or less of the average crystal grain size pa in the sheet-thickness central portion.

In this case, the variation in crystal grain size is small, the crystal grains are uniform and refined, and the occurrence of tears during cutting can be further suppressed. In addition, when using the hot-rolled copper alloy sheet as a sputtering target, it is possible to further suppress the occurrence of abnormal discharge during high-output sputtering.

In addition, in the hot-rolled copper alloy sheet according to one aspect of the present invention, a ratio μ_{B}/μ_{A} of an average crystal grain size μ_{B} in a sheet-thickness surface layer portion to the average crystal grain size μ_{A} in the sheet-thickness central portion is preferably in a range of 0.7 or more and 1.3 or less.

In one aspect of the present invention, the sheet-thickness surface layer portion is a region from the surface (interface between the oxide and copper) of the hot-rolled copper alloy sheet to a position 1 mm away therefrom in the sheet thickness direction.

In this case, the difference in average crystal grain size is small between the sheet-thickness surface layer portion and the sheet-thickness central portion, and when using the hot-rolled copper alloy sheet as a sputtering target, the crystal grain size does not significantly change even in a case where sputtering progresses from the sheet-thickness surface layer portion to the sheet-thickness central portion. Thus, it is possible to suppress the occurrence of abnormal discharge during sputtering, and it is possible to stably deposit a film by sputtering for a long time.

Furthermore, in the hot-rolled copper alloy sheet according to one aspect of the present invention, when the crystal orientation distribution function is expressed in Euler angle representation, an average orientation density in a range in which φ²=0°, φ1=0°, and Φ=0° to 90° is preferably 3.0 or less.

In this case, there are only a few regions where high strain has been introduced during working, and thus when using the hot-rolled copper alloy sheet as a sputtering target, it is possible to suppress the occurrence of unevenness on the sputtering surface due to the level of the strain, thus the occurrence of abnormal discharge is suppressed, and it is possible to stably deposit a film by sputtering for a long time.

In addition, in the hot-rolled copper alloy sheet according to one aspect of the present invention, when the crystal orientation distribution function is expressed in Euler angle representation, an average orientation density in a range in which φ2=45°, φ1=0° to 90°, and Φ=900 is preferably 3.0 or less.

In this case, there are only a few regions where high strain has been introduced during working, and thus when using the hot-rolled copper alloy sheet as a sputtering target, it is possible to suppress the occurrence of unevenness on the sputtering surface due to the level of the strain, thus the occurrence of abnormal discharge is suppressed, and it is possible to stably deposit a film by sputtering for a long time.

A sputtering target according to one aspect of the present invention includes the above-described hot-rolled copper alloy sheet.

According to the sputtering target having the above-described configuration, since the sputtering target includes the above-described hot-rolled copper alloy sheet, it is possible to suppress the occurrence of tears during cutting, and the surface quality is excellent. In addition, it is possible to suppress the occurrence of abnormal discharge during high-output sputtering.

### Advantageous Effects of Invention

According to one aspect of the present invention, it is possible to provide a hot-rolled copper alloy sheet and a sputtering target, and the hot-rolled copper alloy sheet has excellent cuttability and can sufficiently suppress abnormal discharge even in a case where the hot-rolled copper alloy sheet is used as a sputtering target.

### BRIEF DESCRIPTION OF THE DRAWINGS

The FIGURE is a flow diagram of a method of producing a hot-rolled copper alloy sheet (sputtering target) according to the present embodiment.

### DETAILED DESCRIPTION OF THE INVENTION

Hereinafter, a hot-rolled copper alloy sheet and a sputtering target according to one embodiment of the present invention will be described.

The hot-rolled copper alloy sheet according to the present embodiment is used as a hot worked product such as a sputtering target, a backing plate, an electron tube for an accelerator, or a magnetron, and in the present embodiment, the hot-rolled copper alloy sheet is used as a sputtering target for depositing a copper alloy thin film for wiring.

The hot-rolled copper alloy sheet according to the present embodiment has a composition containing Mg in an amount of 0.2 mass % or more and 2.1 mass % or less, and Al in an amount of 0.4 mass % or more and 5.7 mass % or less, with a remainder of Cu and inevitable impurities, in which among the inevitable impurities, an amount of Fe is 0.0020 mass % or less, an amount of O is 0.0020 mass % or less, an amount of S is 0.0030 mass % or less, and an amount of P is 0.0010 mass % or less.

In the hot-rolled copper alloy sheet according to the present embodiment, a special grain boundary length ratio (Lσ/L) in a sheet-thickness central portion is 20% or more, and an average crystal grain size μ_{A} is 40 μm or less.

In addition, in the hot-rolled copper alloy sheet according to the present embodiment, a standard deviation σ_{A} of the crystal grain sizes in the sheet-thickness central portion is preferably 90% or less of the average crystal grain size μ_{A} in the sheet-thickness central portion.

Furthermore, in the hot-rolled copper alloy sheet according to the present embodiment, a ratio μ_{B}/μ_{A} of an average crystal grain size μ_{B} in a sheet-thickness surface layer portion to the average crystal grain size μ_{A} in the sheet-thickness central portion is preferably in a range of 0.7 or more and 1.3 or less.

In the present embodiment, the sheet-thickness central portion is a region of 45% to 55% of the total thickness from the surface (interface between the oxide and copper) of the hot-rolled copper alloy sheet in a sheet thickness direction. In addition, the sheet-thickness surface layer portion is a region from the surface (interface between the oxide and copper) of the hot-rolled copper alloy sheet to a position 1 mm away therefrom in the sheet thickness direction.

Furthermore, in the hot-rolled copper alloy sheet according to the present embodiment, when the crystal orientation distribution function is expressed in Euler angle representation, an average orientation density in a range in which φ2=0°, φ1=0°, and Φ=0° to 90° is preferably 3.0 or less.

In addition, in the hot-rolled copper alloy sheet according to the present embodiment, when the crystal orientation distribution function is expressed in Euler angle representation, an average orientation density in a range in which φ2=45°, φ1=0° to 90°, and Φ=90° is preferably 3.0 or less.

In the hot-rolled copper alloy sheet according to the present embodiment, the reasons for specifying the component composition and the texture as described above will be described.

(Mg)

Mg has an effect of refining the crystal grain size of the hot-rolled copper alloy sheet. In addition, Mg improves migration resistance by suppressing the occurrence of thermal defects such as hillocks and voids in a copper alloy thin film constituting a wiring film of a thin film transistor. Furthermore, an oxide layer containing Mg is formed on a front surface and a back surface of the copper alloy thin film during a heat treatment; and thereby, Si or the like as a main component of a glass substrate and a Si film is prevented from diffusing and permeating into the copper alloy wiring film. Accordingly, Mg prevents an increase in specific resistance of the copper alloy wiring film. In addition, Mg acts to improve the adhesion of the copper alloy wiring film to the glass substrate and the Si film. In order to describe the action of Mg in more detail, the oxide layer containing Mg has both the following two effects.
(1) In a case where Si permeates into the copper alloy wiring film, there is a concern that dielectric breakdown may occur. The oxide layer containing Mg serves as a barrier layer.
(2) The adhesion between Cu and the glass substrate is not good. The oxide layer containing Mg acts to improve the adhesion between the copper alloy wiring film and the glass substrate.

In a case where an amount of Mg is less than 0.2 mass %, there is a concern that the above-described effects may not be achieved. Meanwhile, in a case where the amount of Mg is more than 2.1 mass %, the specific resistance value increases and the wiring film does not exhibit sufficient functions. Therefore, the amount of Mg of more than 2.1 mass % is not preferable.

Therefore, in the present embodiment, the amount of Mg is in a range of 0.2 mass % or more and 2.1 mass % or less.

In order to further exhibit the above-described effects, the lower limit of the amount of Mg is more preferably 0.3 mass % or more, and even more preferably 0.4 mass % or more. Meanwhile, in order to further suppress an increase in specific resistance value, the upper limit of the amount of Mg is more preferably 1.5 mass % or less, and even more preferably 1.2 mass % or less.

(Al)

Al has an effect of increasing a special grain boundary ratio of the hot-rolled copper alloy sheet when being contained together with Mg. In addition, in a copper alloy thin film deposited using a sputtering target containing Al and Mg together, a multiple oxide or oxide solid solution of Mg, Cu, and Al is formed on a surface of the copper alloy thin film by a heat treatment, and thus adhesion and chemical stability are improved.

In a case where an amount of Al of the hot-rolled copper alloy sheet is less than 0.4 mass %, there is a concern that the above-described effects may not be achieved. Meanwhile, in a case where the amount of Al of the hot-rolled copper alloy sheet is more than 5.7 mass %, an average orientation density in a range in which φ2=0°, φ1=0°, and Φ=0° to 90° and an average orientation density in a range in which φ2=45°, φ1=0° to 90°, and Φ=900 increase. Therefore, the amount of Al of more than 5.7 mass % is not preferable. Furthermore, when using as a wiring film, the specific resistance value of the hot-rolled copper alloy sheet increases, and thus the wiring film does not exhibit sufficient functions.

Therefore, in the present embodiment, the amount of Al is in a range of 0.4 mass % or more and 5.7 mass % or less.

In order to further exhibit the above-described effects, the lower limit of the amount of Al is more preferably 0.6 mass % or more, and even more preferably 0.9 mass % or more. Meanwhile, in order to further suppress an increase in specific resistance value, the upper limit of the amount of Al is more preferably 5.0 mass % or less, and even more preferably 4.2 mass % or less.

(Fe, O, S, P)

There is a concern that among the inevitable impurities, elements such as Fe, O, S, and P may reduce the special grain boundary length ratio.

Therefore, in the present embodiment, an amount of Fe is 0.0020 mass % or less, an amount of O is 0.0020 mass % or less, an amount of S is 0.0030 mass % or less, and an amount of P is 0.0010 mass % or less.

The upper limit of the amount of Fe is preferably 0.0015 mass % or less, and more preferably 0.0010 mass % or less. The upper limit of the amount of O is preferably 0.0010 mass % or less, and more preferably 0.0005 mass % or less. The upper limit of the amount of S is preferably 0.0020 mass % or less, and more preferably 0.0015 mass % or less. The upper limit of the amount of P is preferably 0.0005 mass % or less, and more preferably 0.0003 mass % or less.

(Other Inevitable Impurities)

Examples of other inevitable impurities other than the above-described elements include Ag, As, B, Ba, Be, Bi, Ca, Cd, Cr, Sc, rare earth elements, V, Nb, Ta, Mo, Ni, W, Mn, Re, Ru, Sr, Ti, Os, Co, Rh, Ir, Pb, Pd, Pt, Au, Zn, Zr, Hf, Hg, Ga, In, Ge, Y, Tl, N, Sb, Se, Si, Sn, Te, and Li. These inevitable impurities may be contained within a range not to affect the characteristics.

Since there is a concern that these inevitable impurities may reduce the special grain boundary length ratio, an amount of the inevitable impurities is preferably reduced.

(Special Grain Boundary Length Ratio)

A crystal grain boundary is defined as a boundary between two adjacent crystals in a case where an orientation direction difference between the crystals is 150 or more as a result of two-dimensional cross-sectional observation.

A special grain boundary is a crystal grain boundary (coincidence boundary) with a Σ value satisfying a relationship of 3≤Σ≤29, and the Σ value is crystallographically defined based on the CSL theory (Kronberg et al.: Trans. Met. Soc. AIME, 185, 501 (1949)). The coincidence boundary is defined as a crystal grain boundary in which an intrinsic corresponding site lattice orientation defect Dq at the grain boundary satisfies a relationship of Dq≤15°/Σ^{1/2} (D. G. Brandon: Acta. Metallurgica. Vol. 14, p. 1,479, (1966)).

In a case where the special grain boundary length ratio is high in all the crystal grain boundaries, the crystal grain boundaries have improved coincidence. Thus, the abnormal discharge of the sputtering target is reduced, and the occurrence of tears can be suppressed.

Therefore, in the hot-rolled copper alloy sheet according to the present embodiment, the special grain boundary length ratio (Lσ/L) which is a ratio of the sum LG of lengths of special grain boundaries with 3≤Σ≤29 to a length L of all measured crystal grain boundaries in the sheet-thickness central portion is set to 20% or more.

The special grain boundary length ratio (Lσ/L) is preferably 30% or more, and more preferably 40% or more.

In addition, the upper limit of the special grain boundary length is not particularly limited, but is preferably 80% or less in order to suppress an increase in production cost.

(Average Crystal Grain Size in Sheet-Thickness Central Portion)

In the hot-rolled copper alloy sheet according to the present embodiment, in a case where the average crystal grain size μ_{A} in the sheet-thickness central portion (a region of 45% to 55% of the total thickness from the surface (interface between the oxide and copper) of the hot-rolled copper alloy sheet in the sheet thickness direction) is fine, fine tears are less likely to occur on the surface during cutting. In addition, when using the hot-rolled copper alloy sheet as a sputtering target, the unevenness during sputtering is fine in a case where the crystal grain size is fine. Accordingly, abnormal discharge is suppressed, and sputtering characteristics are improved.

Therefore, in the hot-rolled copper alloy sheet according to the present embodiment, the average crystal grain size μA in the sheet-thickness central portion is specified to be 40 μm or less.

The average crystal grain size μ_{A} in the sheet-thickness central portion is preferably 30 μm or less, and more preferably 25 μm or less. In addition, the average crystal grain size pa in the sheet-thickness central portion is preferably 5 μm or more.

(Standard Deviation of Crystal Grain Sizes in Sheet-Thickness Central Portion)

In the hot-rolled copper alloy sheet according to the present embodiment, in a case where the standard deviation σ_{A} of the crystal grain sizes in the sheet-thickness central portion is sufficiently small, the variation in crystal grain size is reduced. Accordingly, when using the hot-rolled copper alloy sheet as a sputtering target, the unevenness of every crystal grain due to sputtering is uniform, and thus it is possible to further suppress the occurrence of abnormal discharge.

Therefore, in the hot-rolled copper alloy sheet according to the present embodiment, the standard deviation σ_{A} of the crystal grain sizes in the sheet-thickness central portion is preferably set to 90% or less of the average crystal grain size μ_{A} in the sheet-thickness central portion.

The standard deviation σ_{A} of the crystal grain sizes in the sheet-thickness central portion is more preferably 80% or less, and even more preferably 70% or less of the average crystal grain size μ_{A} in the sheet-thickness central portion. In addition, the standard deviation GA of the crystal grain sizes in the sheet-thickness central portion is preferably 10% or more.

(Ratio μ_{B}/μ_{A} of Average Crystal Grain Size μ_{B} in Sheet-Thickness Surface Layer

Portion to Average Crystal Grain Size μA in Sheet-Thickness Central Portion) In the hot-rolled copper alloy sheet according to the present embodiment, in a case where the crystal grain size in the sheet thickness direction is uniform, the unevenness of every crystal grain in sputtering from the sheet-thickness surface layer portion to the sheet-thickness central portion is uniform when using the hot-rolled copper alloy sheet as a sputtering target, and thus it is possible to further suppress the occurrence of abnormal discharge. Therefore, it is possible to stably deposit a film by sputtering for a long time.

Therefore, in the present embodiment, a ratio μ_{B}/μ_{A} of an average crystal grain size μ_{B} in the sheet-thickness surface layer portion (a region from the surface (interface between the oxide and copper) of the hot-rolled copper alloy sheet to a position 1 mm away therefrom in the sheet thickness direction) to the average crystal grain size μ_{A} in the sheet-thickness central portion (a region of 45% to 55% of the total thickness from the surface (interface between the oxide and copper) of the hot-rolled copper alloy sheet in the sheet thickness direction) is preferably in a range of 0.7 or more and 1.3 or less.

In the hot-rolled copper alloy sheet according to the present embodiment, the lower limit of the ratio μ_{B}/μ_{A} of the average crystal grain size μ_{B} in the sheet-thickness surface layer portion to the average crystal grain size μ_{A} in the sheet-thickness central portion is preferably 0.8 or more, and more preferably 0.9 or more. Meanwhile, the upper limit of the ratio μ_{B}/μ_{A} of the average crystal grain size μ_{B} in the sheet-thickness surface layer portion to the average crystal grain size μ_{A} in the sheet-thickness central portion is preferably 1.2 or less, and more preferably 1.1 or less.

(Average Orientation Density in Range in which φ2=0°, φ1=0°, and Φ=0° to 90°)

The Euler angle represents the crystal orientation based on the relationship between the specimen coordinate system and the crystal axes of individual crystal grains, and the crystal orientation is expressed by rotating (φ1, Φ, φ2) around the (Z-X-Z) axes from a state where crystal axes (X-Y-Z) match each other. The distribution of the crystal orientation density in a measurement range can be confirmed by displaying the crystal orientation distribution function (ODF) in a three-dimensional Eulerian space using a series expansion method. The orientation density distribution defines a completely random orientation state obtained from a standard powder specimen or the like as 1, and for example, in a case where the orientation density in a certain orientation is 3, this means that the orientation density in this certain orientation is three times more present than random orientation.

The orientation densities in a range in which φ2=0°, φ1=0°, and Φ=0° to 90°, expressed in terms of Euler angles (φ1, φ, φ2), are regions where high strain has been introduced during working and the sputtering efficiency is different from that in other regions. Accordingly, unevenness due to the level of the strain is likely to occur, and abnormal discharge is likely to occur.

Therefore, in the present embodiment, in order to further suppress the occurrence of abnormal discharge in a case where sputtering progresses, the average orientation density in a range in which φ2=0°, φ1=0°, and Φ=0° to 90° is preferably 3.0 or less.

The upper limit of the average orientation density in a range in which φ2=0°, φ1=0°, and Φ=0° to 90° is more preferably 2.7 or less, and even more preferably 2.5 or less. Meanwhile, the lower limit of the average orientation density in a range in which φ2=0°, φ1=0°, and Φ=0° to 90° is not particularly limited, but is more preferably 0.3 or more, and even more preferably 0.5 or more.

(Average Orientation Density in Range in Which φ2=45°, φ1=0° to 90°, and φ=90°)

The orientation densities in a range in which φ2=45°, φ1=0° to 90°, and Φ=90°, expressed in terms of Euler angles (φ1, Φ, φ2), are regions where high strain has been introduced during working and the sputtering efficiency is different from that in other regions. Accordingly, unevenness due to the level of the strain is likely to occur, and abnormal discharge is likely to occur.

Therefore, in the present embodiment, in order to further suppress the occurrence of abnormal discharge in a case where sputtering progresses, the average orientation density in a range in which φ2=45°, φ1=0° to 90°, and Φ=900 is preferably 3.0 or less.

The upper limit of the average orientation density in a range in which φ2=45°, φ1=0° to 90°, and Φ=900 is more preferably 2.6 or less, and even more preferably 2.4 or less. Meanwhile, the lower limit of the average orientation density in a range in which φ2=45°, φ1=0° to 90°, and Φ=900 is not particularly limited, but is more preferably 0.3 or more, and even more preferably 0.5 or more.

Next, a method of producing the hot-rolled copper alloy sheet according to the present embodiment (a method of producing a sputtering target) which has the above-described configuration will be described with reference to the flow diagram shown in the FIGURE.

(Melting and Casting Step S01)

First, the above-described elements are added to molten copper obtained by melting a copper raw material to adjust components, and thus a molten copper alloy is produced. Further, a single element, a master alloy, or the like can be used for addition of various elements. In addition, raw materials containing the above-described elements may be melted together with the copper raw material. Further, a recycled material or a scrap material of the alloy of the embodiment may be used.

As the copper raw material, so-called 4N Cu having a purity of 99.99 mass % or more or so-called 5N Cu having a purity of 99.999 mass % or more is preferably used.

In order to suppress oxidation of Mg and to reduce the hydrogen concentration during melting, it is preferable that the melting is carried out in an atmosphere using an inert gas atmosphere (for example, Ar gas) in which the vapor pressure of H₂O is low and the holding time for the melting is set to the minimum.

Further, the molten copper alloy in which the components have been adjusted is poured into a mold to produce a copper alloy ingot. In consideration of mass production, a continuous casting method or a semi-continuous casting method is preferably used.

(Hot Working Step S02)

Next, the obtained copper alloy ingot is subjected to hot working. In the present embodiment, hot rolling is performed to obtain a hot-rolled copper alloy sheet according to the present embodiment.

The rolling ratio in each pass in the hot rolling step is 50% or less, and the total rolling ratio in the rolling is 98% or less. Regarding final four passes, in a case where the rolling ratio in each pass is less than 5%, the crystal grains in the surface layer portion and the central portion become coarse, and in a case where the rolling ratio in each pass is more than 40%, the special grain boundary length ratio decreases. Therefore, the rolling ratio in each of the final four passes is set to be 5% to 40%. Furthermore, regarding the final four passes, in order to increase the special grain boundary length ratio, the rolling ratio in each pass is preferably reduced as the passes progress.

The “final four passes” refer to four passes that are performed at the end of the multi-pass hot rolling step. For example, in a case where ten passes are performed during hot rolling, final four passes mean the 7th pass, the 8th pass, the 9th pass, and the 10th pass.

In addition, in a case where the starting temperature before the final four passes in the hot rolling step described above is 600° C. or lower, the special grain boundary length ratio decreases, and in a case where the starting temperature before the final four passes is 850° C. or higher, the crystal grains become coarse. In addition, in a case where the end temperature after the final four passes is 550° C. or lower, the special grain boundary length ratio decreases, and in a case where the end temperature after the final four passes is 800° C. or higher, the crystal grains become coarse.

Therefore, in the present embodiment, the starting temperature before the final four passes is preferably higher than 600° C. and lower than 850° C. In addition, the end temperature after the final four passes is preferably higher than 550° C. and lower than 800° C.

Furthermore, in a case where the cooling rate from the end of hot rolling to a temperature of 200° C. or lower is smaller than 200° C./min, the crystal grains in the sheet-thickness central portion become coarse, and there is a concern that the variation in grain size may increase.

Therefore, in the present embodiment, the cooling rate from the end of hot rolling to a temperature of 200° C. or lower is preferably 200° C./min or more.

After finish hot rolling, in order to adjust the shape of the hot-rolled copper alloy sheet, cold rolling with a rolling ratio of 10% or less or shape correction with a leveler may be performed.

(Cutting Step S03)

A sputtering target is produced by cutting the obtained hot-rolled copper alloy sheet according to the present embodiment.

The hot-rolled copper alloy sheet according to the present embodiment having the above-described configuration contains Mg in an amount of 0.2 mass % or more and 2.1 mass % or less, and Al in an amount of 0.4 mass % or more and 5.7 mass % or less, with a remainder of Cu and inevitable impurities, and among the inevitable impurities, an amount of Fe is 0.0020 mass % or less, an amount of O is 0.0020 mass % or less, an amount of S is 0.0030 mass % or less, and an amount of P is 0.0010 mass % or less. Therefore, by controlling the conditions of the hot working process, it is possible to refine the crystal grains and to increase the special grain boundary length ratio.

In addition, in the hot-rolled copper alloy sheet according to the present embodiment, the average crystal grain size μ_{A} in the sheet-thickness central portion is 40 μm or less, and the special grain boundary length ratio (Lσ/L) is 20% or more. Therefore, it is possible to suppress the occurrence of tears during cutting. In addition, when using the hot-rolled copper alloy sheet as a sputtering target, it is possible to suppress the occurrence of abnormal discharge during high-output sputtering.

In addition, in the present embodiment, in a case where the standard deviation σ_{A} of the crystal grain sizes in the sheet-thickness central portion is 90% or less of the average crystal grain size μA in the sheet-thickness central portion, the variation in crystal grain size is small, and thus the crystal grains are uniform and refined. Therefore, it is possible to further suppress the occurrence of tears during cutting. In addition, when using the hot-rolled copper alloy sheet as a sputtering target, it is possible to further suppress the occurrence of abnormal discharge during sputtering.

Furthermore, in the present embodiment, in a case where the ratio μ_{B}/μ_{A} of the average crystal grain size μ_{B} in the sheet-thickness surface layer portion to the average crystal grain size μ_{A} in the sheet-thickness central portion is in a range of 0.7 or more and 1.3 or less, the difference in average crystal grain size is small between the sheet-thickness surface layer portion and the sheet-thickness central portion. When using the hot-rolled copper alloy sheet as a sputtering target, the crystal grain size does not significantly change even in a case where sputtering progresses. Thus, it is possible to suppress the occurrence of abnormal discharge in sputtering from the sheet-thickness surface layer portion to the sheet-thickness central portion, and it is possible to stably deposit a film by sputtering for a long time.

In addition, in the present embodiment, when the crystal orientation distribution function is expressed in Euler angle representation, in a case where an average orientation density in a range in which φ2=0°, φ1=0°, and Φ=0° to 90° is 3.0 or less, the region where high strain has been introduced during working has a low orientation density. When using the hot-rolled copper alloy sheet as a sputtering target, it is possible to suppress the occurrence of unevenness on the sputtering surface due to the level of the strain, it is possible to suppress the occurrence of abnormal discharge during sputtering, and it is possible to stably deposit a film by sputtering for a long time.

Furthermore, in the present embodiment, when the crystal orientation distribution function is expressed in Euler angle representation, in a case where an average orientation density in a range in which φ2=45°, φ1=0° to 90°, and Φ=900 is 3.0 or less, the region where high strain has been introduced during working has a low orientation density. When using the hot-rolled copper alloy sheet as a sputtering target, it is possible to suppress the occurrence of unevenness on the sputtering surface due to the level of the strain, it is possible to suppress the occurrence of abnormal discharge during sputtering, and it is possible to stably deposit a film by sputtering for a long time.

The hot-rolled copper alloy sheet according to the present embodiment has been described, but the present invention is not limited thereto and can be appropriately modified without departing from the technical features of the present invention.

For example, in the above-described embodiment, an example of the method of producing the hot-rolled copper alloy sheet has been described, but the method of producing the copper alloy is not limited to the producing method described in the embodiment, and a producing method of the related art may be appropriately selected for production.

### EXAMPLES

Hereinafter, results of confirmation experiments performed to confirm the effects of the present invention will be described.

### Invention Examples

Oxygen-free copper (99.99 mass % or more) was melted in an Ar gas atmosphere by a heating furnace. Mg and Al were added to the obtained molten metal to produce a copper alloy ingot using a continuous casting machine. The dimensions of the material before rolling were width: 620 mm×length: 1000 mm×thickness: 250 mm, and a rolling step was performed under conditions shown in Table 2 to produce a hot-rolled copper alloy sheet.

A rolling ratio in each pass in the hot rolling step was 50% or less, and a total rolling ratio in the hot rolling was 98% or less. A rolling ratio in each of final four passes was 5% to 40%. In addition, a starting temperature before the final four passes and an end temperature after the final four passes in the above-described hot rolling step are shown in Table 2. The temperature was measured by measuring a surface temperature of the rolled sheet using a radiation thermometer.

After this hot rolling was ended, the rolled sheet was cooled by water cooling at a cooling rate of 200° C./min or more until the temperature reached 200° C. or lower.

### Comparative Examples

Oxygen-free copper (99.99 mass % or more) was melted in an Ar gas atmosphere by a heating furnace. Mg and Al were added to the obtained molten metal to produce a copper alloy ingot using a continuous casting machine. The dimensions of the material before rolling were width: 620 mm×length: 1000 mm×thickness: 250 mm, and a rolling step was performed under conditions shown in Table 2 to produce a hot-rolled copper alloy sheet.

A rolling ratio in each pass in the hot rolling step was 50% or less, and a total rolling ratio in the hot rolling was 98% or less. In addition, a starting temperature before the final four passes and an end temperature after the final four passes in the above-described hot rolling step are shown in Table 2. The temperature was measured by measuring a surface temperature of the rolled sheet using a radiation thermometer.

After this hot rolling was ended, the rolled sheet was cooled by water cooling or air cooling until the temperature reached 200° C. or lower.

An average crystal grain size was measured in a sheet-thickness surface layer portion (a region from the surface (interface between the oxide and copper) of the hot-rolled copper alloy sheet to a position 1 mm away therefrom in the sheet thickness direction) and a sheet-thickness central portion (a region of 45% to 55% of the total thickness from the surface (interface between the oxide and copper) of the hot-rolled copper alloy sheet in the sheet thickness direction) of each of the hot-rolled copper alloy sheets of Invention Examples 1 to 18 and Comparative Examples 1 to 10 obtained as described above. The number of times of abnormal discharge in a case where the hot-rolled copper alloy sheet was used as a sputtering target was evaluated. In addition, the special grain boundary length ratio (Lσ/L), the orientation density, and the standard deviation of the crystal grain sizes in the sheet-thickness central portion were measured. The state of tears during milling task was also evaluated.

(Composition Analysis)

A measurement specimen was collected from the obtained ingot. The amounts of Mg and Al were measured by an inductively coupled plasma optical emission spectrometry. The amount of Fe was measured by inductively coupled plasma mass spectrometry. The amount of O was measured by an inert gas fusion-infrared absorption spectrometry. The amount of S was measured by a combustion-infrared absorption method. The amount of P was measured by an optical emission spectrometry. Further, the measurement was performed at two sites, a central portion of the specimen and an end portion of the specimen in the width direction, and the larger amount was defined as the amount of the sample. As a result, it was confirmed that the component compositions were as shown in Table 1. Fe, O, S, and P in Table 1 were inevitable impurities.

(Average Crystal Grain Size)

An average crystal grain size was calculated in the sheet-thickness surface layer portion and the sheet-thickness central portion of the obtained hot-rolled copper alloy sheet. In addition, a standard deviation of the crystal grain sizes was calculated in the sheet-thickness central portion. For each specimen, the sheet-thickness surface layer portion and the sheet-thickness central portion in a surface perpendicular to the width direction of rolling of the copper alloy sheet, that is, a transverse-direction (TD) surface were subjected to machine polishing by using waterproof abrasive paper and diamond abrasive grains. Next, finish polishing was performed using a colloidal silica solution. Then, the observation surface was measured in a measurement area of 150000 μm² or more at a measurement interval of 1 μm and at an electron beam acceleration voltage of 15 kV by an EBSD method using an EBSD measuring device (Quanta FEG 450, manufactured by FEI, and OIM Data Collection, manufactured by EDAX/TSL (currently AMETEK)) and analysis software (OIM Data Analysis ver. 7.3.1, manufactured by EDAX/TSL). The measurement results were analyzed by the data analysis software OIM to obtain a confidence index (CI) value at each measurement point. The measurement points where the CI value was 0.1 or less were removed, and the orientation difference between crystal grains was analyzed by the data analysis software OIM. A boundary between adjacent measurement points where the orientation difference between the measurement points was 150 or more was defined as a crystal grain boundary. The average crystal grain size and the standard deviation were obtained by an area fraction, that is, an area ratio using the data analysis software OIM.

(Special Grain Boundary Length Ratio (Lσ/L))

A special grain boundary length ratio (Lσ/L) was calculated in the obtained hot-rolled copper alloy sheet. For each specimen, the sheet-thickness center of a surface perpendicular to the width direction of rolling of the copper alloy sheet, that is, a transverse-direction (TD) surface was subjected to machine polishing by using waterproof abrasive paper and diamond abrasive grains on. Next, finish polishing was performed using a colloidal silica solution. Then, the observation surface was measured in a measurement area of 150000 μm² or more at a measurement interval of 1 μm and at an electron beam acceleration voltage of 15 kV by an EBSD method using an EBSD measuring device (Quanta FEG 450, manufactured by FEI, and OIM Data Collection, manufactured by EDAX/TSL (currently AMETEK)) and analysis software (OIM Data Analysis ver. 7.3.1, manufactured by EDAX/TSL). The measurement results were analyzed by the data analysis software OIM to obtain a CI value at each measurement point. The measurement points where the CI value was 0.1 or less were removed, and the orientation difference between crystal grains was analyzed by the data analysis software OIM. A boundary between adjacent measurement points where the orientation difference between the measurement points was 150 or more was defined as a crystal grain boundary. In addition, a total grain boundary length L of the crystal grain boundaries in the measurement range was measured. The position of the crystal grain boundary in which the interface between the adjacent crystal grains constituted the special grain boundary was determined. Then, a grain boundary length ratio LG/L of the sum LG of lengths of special grain boundaries (crystal grain boundaries with 3≤Σ≤29) to the total grain boundary length L of the crystal grain boundaries measured as described above was obtained and defined as the special grain boundary length ratio (Lσ/L).

(Orientation Density)

Using the above-described sample for measurement, the sheet-thickness central portion was measured by the EBSD method at a measurement interval of 1/10 or less of the average crystal grain size. The measurement results were analyzed by the data analysis software OIM with a measurement area where the total area of a plurality of visual fields was 150000 μm² or more such that a total of 1000 or more crystal grains were included, to obtain a CI value at each measurement point. The measurement points where the CI value was 1 or less were removed, and the texture was analyzed by the data analysis software OIM to obtain a crystal orientation distribution function.

The crystal orientation distribution function obtained by the analysis was expressed in Euler angle representation. Then, an average orientation density in a range in which φ2=0°, φ1=0°, and Φ=0° to 90°, and an average orientation density in a range in which φ2=45°, φ1=0° to 90°, and Φ=900 were obtained.

(State of Tears During Milling Task)

Each specimen was formed into a flat plate of 100×2000 mm, and a surface thereof was cut at a cutting depth of 0.1 mm and at a cutting speed of 5000 m/min by a milling machine using a tool with a carbide edge tip. The number of tear flaws having a length of 100 μm or more was evaluated in a 500 μm-square visual field on the cut surface.

(Number of Times of Abnormal Discharge)

An integrated target including a backing plate part was produced from each specimen so that a target part had a diameter of 152 mm. Two types of targets: a target in which a sputtering surface was a sheet-thickness surface layer portion; and a target in which a sputtering surface was a sheet-thickness central portion were produced from one specimen. The targets were attached to a sputtering device, and until the ultimate vacuum pressure in a chamber reached 2×10⁻⁵ Pa or less, the chamber was evacuated.

Next, with the use of a pure Ar gas as a sputtering gas, discharge was performed for 5 hours at a sputtering output of 1900 W by a direct current (DC) power supply while a sputtering gas atmospheric pressure was set to 0.5 Pa. The total number of times of abnormal discharge was counted by measuring the number of times of abnormal discharge occurring during the discharge using an arc counter attached to the power supply.

TABLE 1

| | | Composition (mass %) | | | | | |
|---|---|---|---|---|---|---|---|
| | | Mg | Al | Fe | O | S | P |
| Invention | 1 | 0.2 | 1.0 | 0.0015 | 0.0011 | 0.0030 | 0.0008 |
| Examples | 2 | 0.8 | 0.9 | 0.0018 | 0.0010 | 0.0017 | 0.0010 |
| | 3 | 1.9 | 0.4 | 0.0011 | 0.0017 | 0.0016 | 0.0007 |
| | 4 | 0.7 | 3.4 | 0.0017 | 0.0005 | 0.0019 | 0.0006 |
| | 5 | 2.1 | 3.6 | 0.0018 | 0.0006 | 0.0021 | 0.0004 |
| | 6 | 1.4 | 5.6 | 0.0016 | 0.0012 | 0.0018 | 0.0005 |
| | 7 | 1.5 | 4.2 | 0.0015 | 0.0008 | 0.0027 | 0.0005 |
| | 8 | 0.9 | 1.5 | 0.0014 | 0.0013 | 0.0014 | 0.0004 |
| | 9 | 0.3 | 2.5 | 0.0016 | 0.0015 | 0.0023 | 0.0003 |
| | 10 | 0.7 | 1.2 | 0.0010 | 0.0005 | 0.0010 | 0.0002 |
| | 11 | 0.9 | 3.8 | 0.0009 | 0.0004 | 0.0009 | 0.0003 |
| | 12 | 0.5 | 2.1 | 0.0017 | 0.0020 | 0.0026 | 0.0009 |
| | 13 | 1.3 | 5.0 | 0.0013 | 0.0007 | 0.0020 | 0.0004 |
| | 14 | 0.4 | 0.6 | 0.0020 | 0.0018 | 0.0028 | 0.0007 |
| | 15 | 1.2 | 2.8 | 0.0010 | 0.0005 | 0.0015 | 0.0003 |
| | 16 | 1.9 | 4.0 | 0.0011 | 0.0012 | 0.0025 | 0.0007 |
| | 17 | 1.0 | 1.2 | 0.0012 | 0.0015 | 0.0021 | 0.0007 |
| | 18 | 1.8 | 5.7 | 0.0017 | 0.0018 | 0.0024 | 0.0006 |
| Comparative | 1 | 0.1 | 0.6 | 0.0018 | 0.0017 | 0.0022 | 0.0007 |
| Examples | 2 | 0.9 | 0.2 | 0.0011 | 0.0012 | 0.0023 | 0.0004 |
| | 3 | 2.0 | 6.4 | 0.0015 | 0.0018 | 0.0026 | 0.0004 |
| | 4 | 1.2 | 2.8 | 0.0265 | 0.0291 | 0.0117 | 0.0203 |
| | 5 | 0.4 | 1.0 | 0.0016 | 0.0011 | 0.0024 | 0.0009 |
| | 6 | 1.5 | 4.8 | 0.0017 | 0.0012 | 0.0021 | 0.0007 |
| | 7 | 1.1 | 3.1 | 0.0019 | 0.0014 | 0.0018 | 0.0004 |
| | 8 | 1.8 | 5.5 | 0.0012 | 0.0016 | 0.0020 | 0.0006 |
| | 9 | 0.5 | 1.6 | 0.0017 | 0.0017 | 0.0015 | 0.0005 |
| | 10 | 0.8 | 4.0 | 0.0011 | 0.0015 | 0.0016 | 0.0008 |

TABLE 2

| | | Hot Rolling Step | | | | | | |
|---|---|---|---|---|---|---|---|---|
| | | Final Four Passes | | | | | | |
| | | Starting | End | Rolling Ratio (%) | | | | Cooling |
| | | Temperature | Temperature | First | Second | Third | Fourth | Rate |
| | | (° C.) | (° C.) | Pass | Pass | Pass | Pass | (° C./min) |
| Invention | 1 | 834 | 785 | 38 | 27 | 18 | 9 | 301 |
| Examples | 2 | 743 | 697 | 37 | 23 | 21 | 15 | 268 |
| | 3 | 787 | 729 | 23 | 18 | 13 | 8 | 279 |
| | 4 | 814 | 771 | 39 | 29 | 19 | 11 | 297 |
| | 5 | 709 | 659 | 38 | 24 | 20 | 14 | 253 |
| | 6 | 623 | 577 | 24 | 19 | 16 | 6 | 223 |
| | 7 | 822 | 778 | 38 | 31 | 20 | 10 | 299 |
| | 8 | 691 | 638 | 36 | 25 | 19 | 16 | 244 |
| | 9 | 608 | 559 | 26 | 20 | 14 | 11 | 207 |
| | 10 | 725 | 691 | 24 | 22 | 20 | 18 | 266 |
| | 11 | 761 | 732 | 23 | 20 | 18 | 15 | 281 |
| | 12 | 794 | 744 | 30 | 27 | 24 | 20 | 287 |
| | 13 | 733 | 682 | 37 | 30 | 25 | 19 | 262 |
| | 14 | 638 | 589 | 24 | 20 | 17 | 15 | 226 |
| | 15 | 749 | 706 | 27 | 22 | 19 | 11 | 237 |
| | 16 | 769 | 723 | 26 | 21 | 15 | 12 | 183 |
| | 17 | 848 | 796 | 10 | 8 | 5 | 4 | 222 |
| | 18 | 659 | 598 | 39 | 36 | 30 | 28 | 239 |
| Comparative | 1 | 751 | 698 | 25 | 21 | 17 | 15 | 270 |
| Examples | 2 | 823 | 776 | 37 | 33 | 27 | 23 | 290 |
| | 3 | 624 | 566 | 23 | 20 | 17 | 10 | 221 |
| | 4 | 717 | 654 | 29 | 26 | 23 | 20 | 254 |
| | 5 | 584 | 529 | 17 | 13 | 9 | 6 | 211 |
| | 6 | 868 | 822 | 38 | 34 | 29 | 21 | 308 |
| | 7 | 654 | 601 | 3 | 3 | 3 | 3 | 236 |
| | 8 | 830 | 782 | 45 | 45 | 45 | 45 | 288 |
| | 9 | 686 | 634 | 10 | 20 | 30 | 40 | 259 |
| | 10 | 722 | 661 | 27 | 24 | 20 | 17 | 60 |

TABLE 3

| | | Evaluation of Characteristics of Hot-Rolled Copper Alloy Sheet | | | | | | |
|---|---|---|---|---|---|---|---|---|
| | | | Average Crystal Grain Size | | | | | |
| | | | Sheet- | | | | Average Orientation | |
| | | Special Grain | Thickness | Sheet-Thickness | | | Density | |
| | | Boundary | Surface Layer | Center | | | φ2 = 0° | φ2 = 45° |
| | | Length Ratio | Grain Size | Grain Size | | | φ1 = 0° | φ1 = 0° to |
| | | Lσ/L | μ_{B} | μ_{A} | σ_{A}/μ_{A} | | Φ = 0° to | 90° |
| | | (%) | (μm) | (μm) | (%) | μ_{B}/μ_{A} | 90° | Φ = 90° |
| Invention | 1 | 38 | 21 | 19 | 85 | 1.1 | 0.7 | 0.8 |
| Examples | 2 | 40 | 23 | 25 | 78 | 0.9 | 0.5 | 0.5 |
| | 3 | 20 | 38 | 40 | 63 | 1.0 | 0.3 | 0.3 |
| | 4 | 31 | 22 | 26 | 71 | 0.8 | 1.9 | 1.8 |
| | 5 | 33 | 24 | 20 | 75 | 1.2 | 2.4 | 2.2 |
| | 6 | 66 | 35 | 31 | 65 | 1.1 | 3.0 | 3.0 |
| | 7 | 34 | 14 | 17 | 80 | 0.8 | 2.5 | 2.4 |
| | 8 | 39 | 19 | 15 | 55 | 1.3 | 1.2 | 1.0 |
| | 9 | 28 | 23 | 22 | 90 | 1.0 | 1.4 | 1.3 |
| | 10 | 58 | 13 | 14 | 45 | 0.9 | 1.1 | 1.0 |
| | 11 | 62 | 16 | 17 | 49 | 0.9 | 0.8 | 0.8 |
| | 12 | 23 | 12 | 18 | 83 | 0.7 | 1.1 | 1.0 |
| | 13 | 60 | 11 | 14 | 70 | 0.8 | 2.7 | 2.6 |
| | 14 | 30 | 20 | 22 | 73 | 0.9 | 0.3 | 0.4 |
| | 15 | 46 | 32 | 30 | 77 | 1.1 | 1.6 | 1.7 |
| | 16 | 58 | 38 | 33 | 91 | 1.2 | 2.3 | 2.4 |
| | 17 | 55 | 54 | 38 | 68 | 1.4 | 0.9 | 0.8 |
| | 18 | 63 | 30 | 36 | 79 | 0.8 | 3.1 | 3.2 |
| Comparative | 1 | 59 | 68 | 77 | 74 | 0.9 | 1.6 | 1.3 |
| Examples | 2 | 11 | 15 | 19 | 67 | 0.8 | 2.3 | 2.0 |
| | 3 | 61 | 23 | 21 | 78 | 1.1 | 3.6 | 3.4 |
| | 4 | 16 | 30 | 29 | 77 | 1.0 | 2.0 | 1.7 |
| | 5 | 8 | 34 | 38 | 74 | 0.9 | 1.3 | 1.0 |
| | 6 | 25 | 60 | 93 | 78 | 0.6 | 2.1 | 1.7 |
| | 7 | 22 | 83 | 56 | 77 | 1.5 | 0.7 | 0.6 |
| | 8 | 6 | 32 | 37 | 76 | 0.9 | 4.1 | 4.0 |
| | 9 | 13 | 34 | 30 | 73 | 1.1 | 2.3 | 2.2 |
| | 10 | 56 | 75 | 102 | 93 | 0.7 | 1.8 | 1.5 |

TABLE 4

| | | Evaluation | | |
|---|---|---|---|---|
| | | | Number of Times of Abnormal | |
| | | | Discharge | |
| | | | Sheet-Thickness | |
| | | Surface State | Surface Layer | Sheet-Thickness |
| | | (number of | Portion | Central Portion |
| | | tears) | (number) | (number) |
| Invention | 1 | 0 | 2 | 1 |
| Examples | 2 | 0 | 1 | 1 |
| | 3 | 1 | 2 | 1 |
| | 4 | 0 | 0 | 0 |
| | 5 | 1 | 2 | 0 |
| | 6 | 0 | 1 | 1 |
| | 7 | 0 | 0 | 1 |
| | 8 | 0 | 0 | 0 |
| | 9 | 1 | 0 | 1 |
| | 10 | 0 | 0 | 0 |
| | 11 | 0 | 0 | 0 |
| | 12 | 1 | 1 | 0 |
| | 13 | 0 | 1 | 0 |
| | 14 | 0 | 1 | 0 |
| | 15 | 0 | 0 | 0 |
| | 16 | 4 | 7 | 5 |
| | 17 | 3 | 5 | 6 |
| | 18 | 2 | 5 | 7 |
| Comparative | 1 | 11 | 41 | 42 |
| Examples | 2 | 10 | 28 | 32 |
| | 3 | 8 | 31 | 33 |
| | 4 | 15 | 42 | 41 |
| | 5 | 9 | 38 | 37 |
| | 6 | 12 | 40 | 56 |
| | 7 | 12 | 44 | 29 |
| | 8 | 6 | 35 | 38 |
| | 9 | 14 | 41 | 41 |
| | 10 | 11 | 42 | 64 |

In Comparative Example 1, the amount of Mg was less than the range of the present embodiment, and the average crystal grain size μ_{A} in the sheet-thickness central portion was 77 μm. In Comparative Example 1, the number of tears during cutting was large, and the number of times of abnormal discharge in the sheet-thickness surface layer portion and the sheet-thickness central portion was large.

In Comparative Example 2, the amount of Al was less than the range of the present embodiment, and the special grain boundary length ratio (Lσ/L) in the sheet-thickness central portion was 11%. In Comparative Example 2, the number of tears during cutting was large, and the number of times of abnormal discharge in the sheet-thickness surface layer portion and the sheet-thickness central portion was large.

In Comparative Example 3, the amount of Al was more than the range of the present embodiment. In Comparative Example 3, the number of tears during cutting was large, and the number of times of abnormal discharge in the sheet-thickness surface layer portion and the sheet-thickness central portion was large.

In Comparative Example 4, the amount of Fe, the amount of O, the amount of S, and the amount of P were more than the ranges of the present embodiment, and the special grain boundary length ratio (Lσ/L) in the sheet-thickness central portion was 16%. In Comparative Example 4, the number of tears during cutting was large, and the number of times of abnormal discharge in the sheet-thickness surface layer portion and the sheet-thickness central portion was large.

In Comparative Example 5, the starting temperature before the final four passes of hot rolling and the end temperature after the final four passes were low, and the special grain boundary length ratio (Lσ/L) in the sheet-thickness central portion was 8%. In Comparative Example 5, the number of tears during cutting was large, and the number of times of abnormal discharge in the sheet-thickness surface layer portion and the sheet-thickness central portion was large.

In Comparative Example 6, the starting temperature before the final four passes of hot rolling and the end temperature after the final four passes were high, and the average crystal grain size μ_{A} in the sheet-thickness central portion was 93 μm. In Comparative Example 6, the number of tears during cutting was large, and the number of times of abnormal discharge in the sheet-thickness surface layer portion and the sheet-thickness central portion was large.

In Comparative Example 7, the rolling ratio in the final four passes of hot rolling was low, and the average crystal grain size μ_{A} in the sheet-thickness central portion was 56 μm. In Comparative Example 7, the number of tears during cutting was large, and the number of times of abnormal discharge in the sheet-thickness surface layer portion and the sheet-thickness central portion was large.

In Comparative Example 8, the rolling ratio in the final four passes of hot rolling was high, and the special grain boundary length ratio (Lσ/L) in the sheet-thickness central portion was 6%. In Comparative Example 8, the number of tears during cutting was large, and the number of times of abnormal discharge in the sheet-thickness surface layer portion and the sheet-thickness central portion was large.

In Comparative Example 9, the rolling ratio in the latter pass of the final four passes of hot rolling was high, and the special grain boundary length ratio (Lσ/L) in the sheet-thickness central portion was 13%. In Comparative Example 9, the number of tears during cutting was large, and the number of times of abnormal discharge in the sheet-thickness surface layer portion and the sheet-thickness central portion was large.

In Comparative Example 10, the cooling rate after hot rolling was 60° C./min which was small, and the average crystal grain size μ_{A} in the sheet-thickness central portion was 102 μm. In Comparative Example 10, the number of tears during cutting was large, and the number of times of abnormal discharge in the sheet-thickness surface layer portion and the sheet-thickness central portion was large.

In contrast, in Invention Examples 1 to 18, the amount of Mg, the amount of Al, the amount of Fe, the amount of O, the amount of S, the amount of P, the special grain boundary length ratio (Lσ/L) in the sheet-thickness central portion, and the average crystal grain size pa in the sheet-thickness central portion were within the ranges of the present embodiment. In Invention Examples 1 to 18, the number of tears during cutting was suppressed to 4 or less, and the number of occurrences of abnormal discharge in the sheet-thickness surface layer portion and the sheet-thickness central portion was 7 or less.

From the results of the above Examples, it has been confirmed that according to Invention Examples, it is possible to provide a hot-rolled copper alloy sheet which has excellent cuttability and can sufficiently suppress abnormal discharge even in a case where the hot-rolled copper alloy sheet is used as a sputtering target, and a sputtering target.

### INDUSTRIAL APPLICABILITY

A hot-rolled copper alloy sheet according to the present embodiment is suitably used as a hot worked product such as a sputtering target, a backing plate, an electron tube for an accelerator, or a magnetron. A sputtering target according to the present embodiment is suitably used for depositing a copper alloy thin film for wiring.

1. A hot-rolled copper alloy sheet comprising:
0.2 mass % or more and 2.1 mass % or less of Mg;
0.4 mass % or more and 5.7 mass % or less of Al; and
a remainder being Cu and inevitable impurities,
wherein among the inevitable impurities, an amount of Fe is 0.0020 mass % or less, an amount of O is 0.0020 mass % or less, an amount of S is 0.0030 mass % or less, and an amount of P is 0.0010 mass % or less,
when measurement is performed in a measurement area of 150000 μm² or more in a sheet-thickness central portion at a measurement interval of 1 μm by an EBSD method, measurement results are analyzed by data analysis software OIM to obtain a CI value at each measurement point, measurement points where the Cl value is 0.1 or less are removed, an orientation difference between crystal grains is analyzed, and a boundary between adjacent measurement points where an orientation difference between the measurement points is 15° or more is defined as a crystal grain boundary, a special grain boundary length ratio which is a ratio (Lσ/L) of a sum La of lengths of special grain boundaries with 3≤Σ≤29 to a length L of all measured crystal grain boundaries is 20% or more, and
an average crystal grain size A in the sheet-thickness central portion is 40 μm or less.

2. The hot-rolled copper alloy sheet according to claim 1,
wherein a standard deviation GA of crystal grain sizes in the sheet-thickness central portion is 90% or less of the average crystal grain size A in the sheet-thickness central portion.

3. The hot-rolled copper alloy sheet according to claim 1,
wherein a ratio μ_{B}/μ_{A} of an average crystal grain size μ_{B} in a sheet-thickness surface layer portion to the average crystal grain size A in the sheet-thickness central portion is in a range of 0.7 or more and 1.3 or less.

4. The hot-rolled copper alloy sheet according to claim 1,
wherein when a crystal orientation distribution function is expressed in Euler angle representation, an average orientation density in a range in which φ2=0°, φ1=0°, and Φ=0° to 90° is 3.0 or less.

5. The hot-rolled copper alloy sheet according to claim 1,
wherein when a crystal orientation distribution function is expressed in Euler angle representation, an average orientation density in a range in which φ2=45°, φ1=0° to 90°, and Φ=90° is 3.0 or less.

6. A sputtering target comprising:
the hot-rolled copper alloy sheet according to claim 1.
